(19) United States
(12) Patent Application Publication
(10) Pub. No.: US 2020/0083183 A1
(43) Pub. Date: Mar. 12, 2020

(54) ELECTRONIC COMPONENT AND ELECTRONIC DEVICE

(71) Applicant: DENSO CORPORATION, Kariya-city (JP)

(72) Inventors: Toshihiko TAKAHATA, Kariya-city (JP); Hiroo ANAN, Kariya-city (JP)

(21) Appl. No.: 16/562,531

(22) Filed: Sep. 6, 2019

(30) Foreign Application Priority Data
Sep. 11, 2018 (JP) 2018-169879

(51) Int. Cl. H01L 23/66; H01L 23/29; H01L 29/93; G01S 7/03

(52) U.S. Cl. CPC H01L 23/66; H01L 23/293; G01S 7/022; G01S 7/032; H01L 29/93

(57) ABSTRACT

An electronic component includes: a variable capacitance element; a substrate that has the variable capacitance element; a connection pattern that is electrically connected to the variable capacitance element; and a sealing member that has permittivity lower than that of the substrate and has insulation resistance higher than that of the substrate. At least a part of the connection pattern is disposed on an outer surface of the sealing member.

### CROSS REFERENCE TO RELATED APPLICATIONS

The present application claims the benefit of priority from Japanese Patent Application No. 2018-169879 filed on Sep. 11, 2018. The entire disclosures of all of the above applications are incorporated herein by reference.

### TECHNICAL FIELD

The present disclosure relates to an electronic device and an electronic component including a variable capacitance element.

### BACKGROUND

An electronic component including a variable capacitance element such as a varactor diode has been known. The electronic component includes a substrate provided with the varactor diode as well as a wiring pattern for connection with a different component member.

The electronic component as well as an antenna, a monolithic microwave integrated circuit (abbreviated as MMIC) chip, and the like may be mounted on a control board to configure a millimeter wave radar device. Such a millimeter wave radar device is configured to change resonance frequency of the antenna by means of the variable capacitance element and reduce electric power loss.

### SUMMARY

The present disclosure describes an electronic component including: a variable capacitance element; a substrate that has the variable capacitance element; a connection pattern that is electrically connected to the variable capacitance element; and a sealing member that has permittivity lower than that of the substrate and has insulation resistance higher than that of the substrate.

### BRIEF DESCRIPTION OF DRAWINGS

Features and advantages of the present disclosure will become more apparent from the following detailed description with reference to the accompanying drawings. In the drawings:

FIG. 1 is a sectional view of an electronic component according to a first embodiment;

FIG. 2 is a graph indicating relation between permittivity and insulation resistance of each material;

FIG. 3 is a sectional view of a millimeter wave radar device including the electronic component depicted in FIG. 1;

FIG. 4A is a view depicting a step of producing the electronic component depicted in FIG. 1;

FIG. 4B is a view subsequent to FIG. 4A, depicting a step of producing the electronic component;

FIG. 4C is a view subsequent to FIG. 4B, depicting a step of producing the electronic component;

FIG. 4D is a view subsequent to FIG. 4C, depicting a step of producing the electronic component;

FIG. 4E is a view subsequent to FIG. 4D, depicting a step of producing the electronic component;

FIG. 4F is a view subsequent to FIG. 4E, depicting a step of producing the electronic component;

FIG. 4G is a view subsequent to FIG. 4F, depicting a step of producing the electronic component;

FIG. 5 is a sectional view of an electronic component according to a modification of the first embodiment;

FIG. 6 is a sectional view of an electronic component according to another modification of the first embodiment;

FIG. 7 is a sectional view of an electronic device according to a second embodiment;

FIG. 8 is a sectional view of a millimeter wave radar device including the electronic device depicted in FIG. 7;

FIG. 9A is a sectional view depicting a step of producing the electronic device depicted in FIG. 7;

FIG. 9B is a sectional view subsequent to FIG. 9A, depicting a step of producing the electronic device;

FIG. 9C is a sectional view subsequent to FIG. 9B, depicting a step of producing the electronic device;

FIG. 9D is a sectional view subsequent to FIG. 9C, depicting a step of producing the electronic device;

FIG. 9E is a sectional view subsequent to FIG. 9D, depicting a step of producing the electronic device;

FIG. 9F is a sectional view subsequent to FIG. 9E, depicting a step of producing the electronic device;

FIG. 9G is a sectional view subsequent to FIG. 9F, depicting a step of producing the electronic device;

FIG. 9H is a sectional view subsequent to FIG. 9G, depicting a step of producing the electronic device;

FIG. 9I is a sectional view subsequent to FIG. 9H, depicting a step of producing the electronic device;

FIG. 10 is a sectional view of an electronic device according to a third embodiment; and

FIG. 11 is a sectional view of an electronic device according to a fourth embodiment.

### DETAILED DESCRIPTION

The electronic component in a related art may be configured particularly not in consideration of a parasitic inductance component or a parasitic capacitance component (i.e., a parasitic LC component) attributable to the wiring pattern. The electronic component may have deterioration or change in characteristic caused by the parasitic inductance component or the parasitic capacitance component.

The present disclosure describes an electronic component and an electronic device inhibiting deterioration and change in characteristic.

According to one aspect of the present disclosure, an electronic component may include: a variable capacitance element; a substrate that has the variable capacitance element; a connection pattern that is electrically connected to the variable capacitance element and is also electrically connected to a mounting target member; and a sealing member that has permittivity lower than that of the substrate and has insulation resistance higher than that of the substrate, the sealing member sealing the substrate. At least a part of the connection pattern may be disposed on an outer surface of the sealing member.

According to this configuration, the sealing member is made of the material lower in permittivity and higher in insulation resistance than the substrate. By providing the connection pattern on the sealing member, it may be possible to reduce parasitic LC component attributable to the connection pattern. It may be possible to prevent characteristic of the electronic component from changing and being deteriorated.

According to another aspect of the present disclosure, an electronic device may include: a variable capacitance element; a substrate that has the variable capacitance element; a connection pattern that is electrically connected to the variable capacitance element and is also electrically connected to a mounting target member; a sealing member that has permittivity lower than that of the substrate and has insulation resistance higher than that of the substrate, the sealing member sealing the substrate; and a conductor pattern that is electrically connected to the variable capacitance element and is configured to function as an antenna. At least a part of the connection pattern may be disposed on an outer surface of the sealing member. The conductor pattern may be disposed on an outer surface of the sealing member.

According to this configuration, the sealing member is made of the material lower in permittivity and higher in insulation resistance than the substrate. By providing the connection pattern on the sealing member, it may be possible to reduce parasitic LC component attributable to the connection pattern. It may be possible to prevent characteristic of the electronic device from changing and being deteriorated.

The sealing member is provided with the conductor pattern functioning as an antenna. There may be no need to provide a control board with an antenna to configure a millimeter wave radar device including the electronic device mounted on the control board serving as a mounting target member. It may be possible to reduce the size of the control board, which will lead to reduction in size of the millimeter wave radar device.

Embodiments of the present disclosure will be described hereinafter with reference to the drawings. Identical or corresponding parts in the embodiments will be denoted by identical reference signs in the description.

### First Embodiment

The first embodiment will be described below. An electronic component according to the present embodiment may be a member configuring a millimeter wave radar device mounted on a vehicle, for example. The millimeter wave radar device is configured to measure distance and relative speed between an own vehicle and a preceding vehicle for adaptive cruise control (i.e., ACC) or the like.

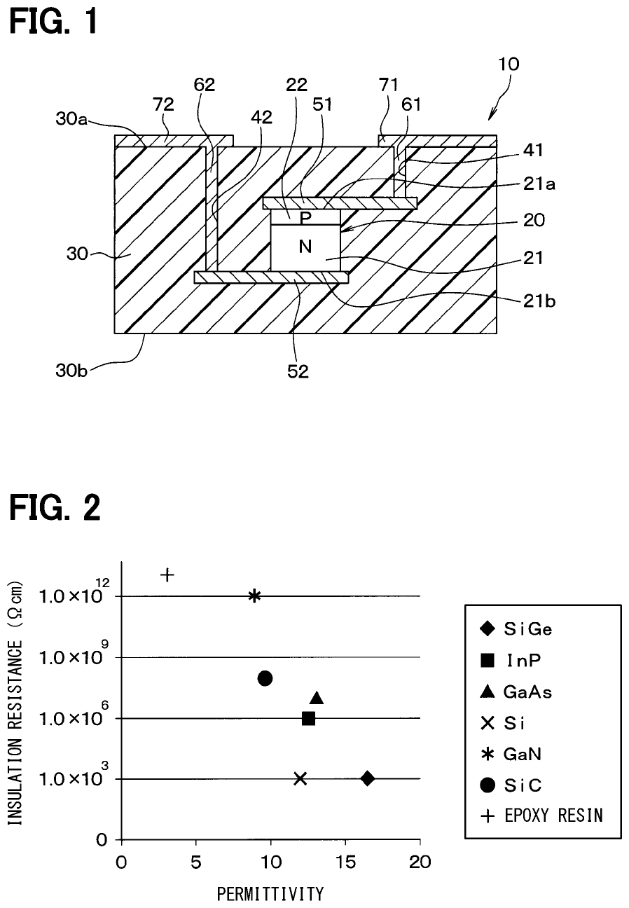

As depicted in FIG. 1, an electronic component 10 includes a substrate 21 provided with a varactor diode 20. The varactor diode 20 may correspond to a variable capacitance element. The substrate 21 according to the present embodiment has a first surface 21a and a second surface 21b opposite to the first surface 21a, and is constituted by an N-type gallium arsenide substrate. The first surface 21a may be referred to as one surface, and the second surface 21b may be referred to as the other surface. The substrate 21 is provided, on the first surface 21a side, with a P-type layer 22 including diffuse impurities. The varactor diode 20 exemplifies the variable capacitance element. The varactor diode is an example of a variable capacitance element, and a variable capacitance diode.

The electronic component 10 includes a sealing member 30 sealing the substrate 21 provided with the varactor diode 20. The sealing member 30 according to the present embodiment has an outline in a substantially rectangular parallelepiped shape having a first surface 30a facing the first surface 21a of the substrate 21, and a second surface 30b facing the second surface 21b of the substrate 21. The first surface 30a and the second surface 30b of the sealing member 30 correspond to outer surfaces of the sealing member 30 in the present embodiment.

The sealing member 30 is made of a material lower in permittivity and higher in insulation resistance than the substrate 21 provided with the varactor diode 20. In other words, the sealing member 30 is made of the material higher in frequency characteristic than the substrate 21. Having high insulation resistance can also be expressed as having a low parasitic inductance component. The sealing member 30 is made of the material lower in parasitic inductance component and parasitic capacitance component (i.e., parasitic LC component) than the substrate 21.

Specifically, as indicated in FIG. 2, the substrate 21 according to the present embodiment is configured by the gallium arsenide substrate having permittivity at 13 and insulation resistance at 1.0×10⁷ Ωcm. The sealing member 30 is made of the material having permittivity less than 13 and insulation resistance more than 1.0×10⁷ Ωcm. The sealing member 30 according to the present embodiment is made of epoxy resin having permittivity at about 3 and insulation resistance at about 1.0×10¹³ Ωcm.

The sealing member 30 is provided therein with a first electrode 51 electrically connected to the first surface 21a (i.e., the P-type layer 22) of the substrate 21, and a second electrode 52 electrically connected to the second surface 21b of the substrate 21. The first electrode 51 according to the present embodiment partially projects, along the plane of the substrate 21, from the first surface 21a of the substrate 21. Specifically, the first electrode 51 has a portion not overlapped with the substrate 21 when viewed along a normal line to the plane of the substrate 21. Similarly, the second electrode 52 partially projects, along the plane of the substrate 21, from the second surface 21b of the substrate 21.

The sealing member 30 is provided with a first via hole 41 exposing the first electrode 51, and a second via hole 42 exposing the second electrode 52. The first via hole 41 and the second via hole 42 extend from the first surface 30a. The first via hole 41 embeds a first through via 61 connected to the first electrode 51. The second via hole 42 embeds a second through via 62 connected to the second electrode 52. The sealing member 30 is provided, on the first surface 30a, with a first connection pattern 71 connected to the first through via 61 and a second connection pattern 72 connected to the second through via 62.

Each of the first electrode 51, the second electrode 52, the first through via 61, the second through via 62, the first connection pattern 71, and the second connection pattern 72 according to the present embodiment is made of copper or the like, and may alternatively be made of aluminum or the like.

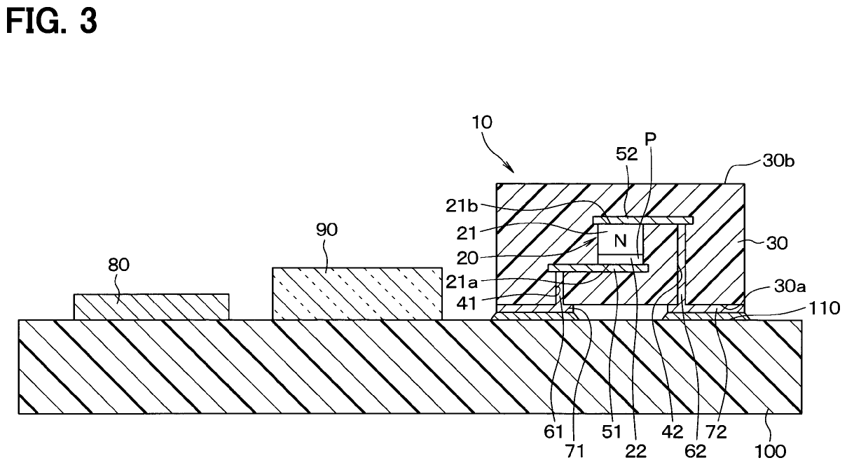

The electronic component 10 according to the present embodiment has been described above in terms of its configuration. As exemplarily depicted in FIG. 3, the electronic component 10 thus configured is mounted on a control board 100 provided with an antenna 80, an MMIC chip 90, a power supply unit (not depicted), and the like, to configure a millimeter wave radar device. Specifically, the electronic component 10 is mounted on the control board 100. The first surface 30a of the sealing member 30 faces the control board 100 and a joint member 110 such as solder is interposed between the first and second connection patterns 71 and 72 and a connection pattern of the control board 100. The MMIC chip 90 may be referred to as a control circuit, and correspond to a mounting target member.

The control board 100 is provided with various signal processing circuits, a microcomputer, and the like. The control board 100 according to the present embodiment corresponds to the mounting target member. The MMIC chip 90 is an oscillator circuit configured to oscillate a radio wave (e.g., a millimeter wave) having a predetermined frequency.

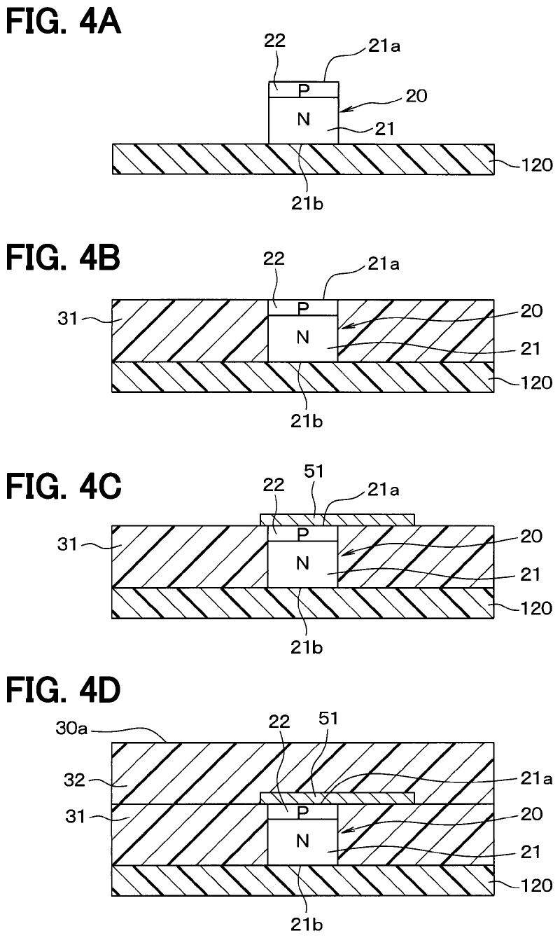

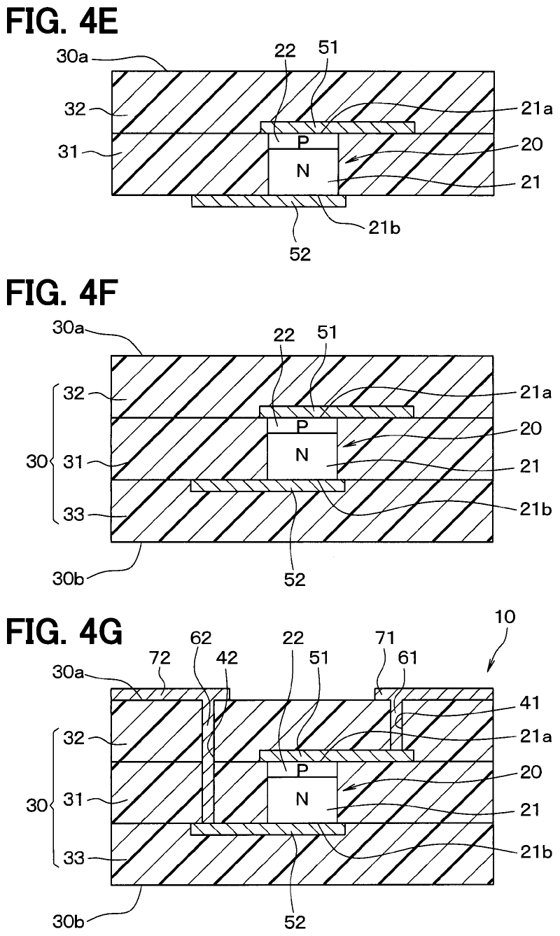

A method for producing the electronic component 10 will be described with reference to FIG. 4A to FIG. 4G.

As depicted in FIG. 4A, the substrate 21 provided with the varactor diode 20 is initially disposed on a preliminarily fixing member 120 to be fixed thereto. The preliminarily fixing member 120 according to the present embodiment may be configured by a thermally foamed sheet having viscosity at normal temperature and decreased in viscosity when heated, for example.

As depicted in FIG. 4B, a first sealing member 31 is subsequently formed to cover side surfaces of the substrate 21 with the first surface 21a of the substrate 21 being exposed, in accordance with a transfer molding method or the like with use of a metal mold (not depicted). The side surfaces connect the first surface 21a and the second surface 21b of the substrate.

As depicted in FIG. 4C, the first electrode 51 is subsequently formed to be electrically connected to the first surface 21a of the substrate 21. The first electrode 51 according to the present embodiment is achieved by forming a metal film made of copper in accordance with a plating method or the like and then patterning the metal film.

As depicted in FIG. 4D, a second sealing member 32 is formed to seal the first electrode 51 in accordance with the transfer molding method or the like with use of a metal mold (not depicted). The first surface 30a of the sealing member 30 is configured by a surface, located distant from the first sealing member 31, of the second sealing member 32.

As depicted in FIG. 4E, the preliminarily fixing member 120 is subsequently heated to be decreased in viscosity, and the preliminarily fixing member 120 is separated from the substrate 21 and the first sealing member 31. The second electrode 52 is then formed to be electrically connected to the second surface 21b of the substrate 21. Similarly to the first electrode 51, the second electrode 52 is achieved by forming a metal film made of copper in accordance with the plating method or the like and then patterning the metal film.

As depicted in FIG. 4F, a third sealing member 33 is then formed to seal the second electrode 52 in accordance with the transfer molding method or the like with use of a metal mold (not depicted). The sealing member 30 is thus configured by the first to third sealing members 31 to 33. The second surface 30b of the sealing member 30 is configured by a surface, located distant from the first sealing member 31, of the third sealing member 33.

As depicted in FIG. 4G, laser light or the like is subsequently applied to the first surface 30a of the sealing member 30 to provide the sealing member 30 with the first via hole 41 exposing the first electrode 51 and the second via hole 42 exposing the second electrode 52. A metal film made of copper is then formed by plating or the like to embed the first via hole 41 and the second via hole 42, so as to achieve the first through via 61 and the second through via 62. A metal film is then formed on the first surface 30a of the sealing member 30 and is patterned to achieve the first connection pattern 71 connected to the first through via 61 and the second connection pattern 72 connected to the second through via 62.

The electronic component 10 is produced as described above. The metal film configuring the first electrode 51 may be formed in accordance with a chemical vapor deposition (CVD) method, a sputtering method, or the like. The metal films configuring the second electrode 52, the first through via 61, the second through via 62, the first connection pattern 71, and the second connection pattern 72 may be similarly formed in accordance with the CVD method, the sputtering method, or the like.

As described above, the electronic component 10 according to the present embodiment includes the sealing member 30 made of the material lower in permittivity and higher in insulation resistance than the substrate 21 provided with the varactor diode 20. The first and second connection patterns 71 and 72 are disposed on the first surface 30a of the sealing member 30. This configuration achieves reduction in parasitic LC component attributable to the first and second connection patterns 71 and 72. This accordingly inhibits change and deterioration in characteristic of the electronic component 10.

The electronic component 10 includes the substrate 21 that is provided with the varactor diode 20 and sealed by the sealing member 30. This configuration achieves reduction in amount of the substrate 21 in comparison to a case where the electronic component 10 is sized identically and is not provided with the sealing member 30. In an exemplary case where the substrate 21 is cut out of a wafer, this configuration leads to increase in the number of substrates 21 produced from the wafer and cost reduction. This configuration achieves significant cost reduction particularly in the case where the substrate 21 is configured by the gallium arsenide substrate, which is expensive.

### Modification of First Embodiment

The modification of the first embodiment will be described below. The first connection pattern 71 and the second connection pattern 72 according to the first embodiment may be appropriately changed in shape if the first connection pattern 71 and the second connection pattern 72 are at least partially provided on the first surface 30a of the sealing member 30.

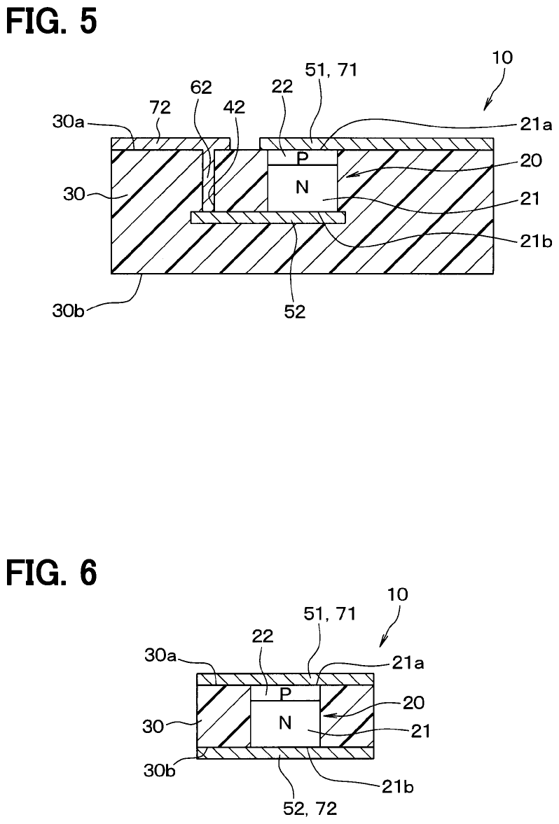

As exemplarily depicted in FIG. 5, the electronic component 10 may include the first electrode 51 and the first connection pattern 71 provided in common with each other. As exemplarily depicted in FIG. 6, the first electrode 51 and the first connection pattern 71 may be provided in common with each other, and the second electrode 52 and the second connection pattern 72 may be provided in common with each other. In such configurations, the first connection pattern 71 and the second connection pattern 72 are provided partially on the first surface 30a of the sealing member 30. When the electronic component 10 thus configured is mounted on the control board 100, the second electrode 52 may be connected to the control board 100 via the joint member 110 and the first electrode 51 may be connected to the control board 100 via a bonding wire or the like.

### Second Embodiment

The second embodiment will be described below. The second embodiment describes an electronic device 130. Specifically, the present embodiment provides the electronic device 130 including the electronic component 10 according to the first embodiment provided with a conductor pattern and the like. The remaining configuration is similar to that according to the first embodiment and will not be described repeatedly.

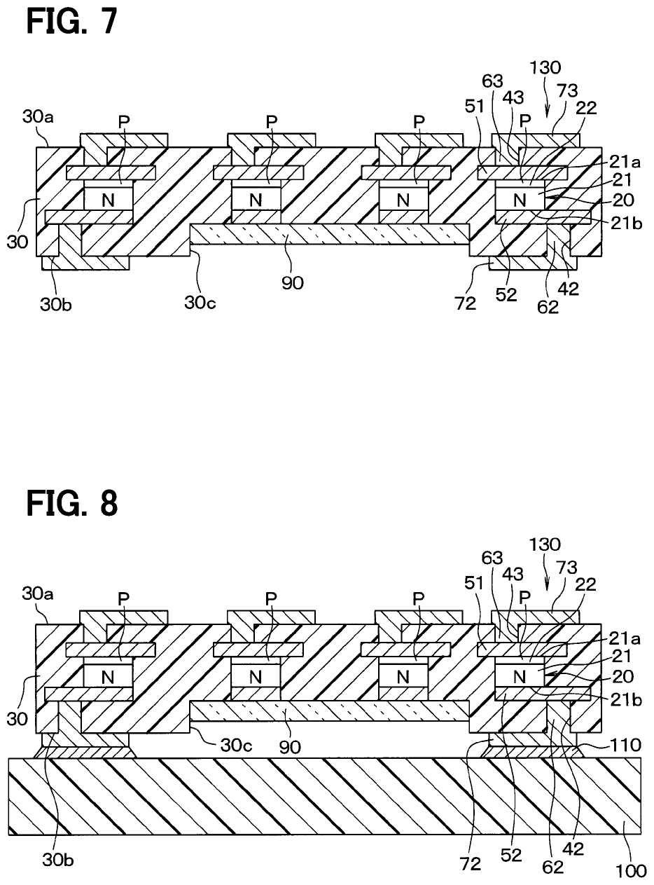

As depicted in FIG. 7, the present embodiment provides an electronic device 130 including multiple substrates 21 each provided with the varactor diode 20. The substrates 21 are integrally sealed by the sealing member 30. Specifically, the substrates 21 have the first surfaces 21a positioned flush with one another and arrayed regularly to be sealed by the sealing member 30.

The sealing member 30 is provided therein with first electrodes 51 each connected to the first surface 21a of a corresponding one of the substrates 21. The sealing member 30 is also provided therein with second electrodes 52 each electrically connected to the second surface 21b of a corresponding one of the substrates 21.

The sealing member 30 is provided with second via holes 42 exposing the second electrodes 52 to the second surface 30b. The second via holes 42 each embed the second through via 62. The sealing member 30 is provided, on the second surface 30b, with second connection patterns 72 each connected to the second through via 62.

Each of the second electrodes 52 connected to a corresponding one of the substrates 21 disposed substantially at a vertical center in FIG. 7 is partially exposed through the second via hole 42 in a section different from the section depicted in FIG. 7 and partially projects from the second surface 21b of the corresponding one of the substrates 21.

The sealing member 30 is also provided with first via holes 41 exposing the first electrodes 51 to the second surface 30b and positioned in a section different from the section depicted in FIG. 7. Each of the first electrodes 51 is partially exposed through a corresponding one of the first via holes 41 and partially projects from the first surface 21a of a corresponding one of the substrates 21. Each of the first via holes 41 embeds the first through via 61, and the sealing member 30 is provided, on the second surface 30b, with first connection patterns 71 each electrically connected to the first through via 61.

The sealing member 30 is also provided with third via holes 43 exposing the first electrodes 51 to the first surface 30a. The third via holes 43 each embed a third through via 63.

The sealing member 30 is provided, on the first surface 30a, with a plurality of conductor patterns 73 respectively connected to the third through vias 63. The plurality of conductor patterns 73 functions as antennas in a millimeter wave radar device. The antennas are disposed directly on the sealing member 30 according to the present embodiment.

The present embodiment provides the substrates 21 arrayed regularly and the conductor patterns 73 arrayed regularly. The plurality of conductor patterns 73 is thus disposed to function as array antennas. The third through vias 63 and the conductor patterns 73 according to the present embodiment are made of copper or the like, similarly to the first and second through vias 61 and 62 and the first and second connection patterns 71 and 72.

The sealing member 30 is further provided, in the second surface 30b, with a recess 30c. The second electrodes 52 respectively connected to the second surfaces 21b of the substrates 21 are appropriately routed to be exposed to a bottom surface of the recess 30c.

The recess 30c is provided with the MMIC chip 90 connected to the second electrodes 52 that are respectively connected to the second surfaces 21b of the substrates 21. The MMIC chip 90 according to the present embodiment corresponds to an oscillator circuit configured to oscillate a radio wave (e.g., a millimeter wave) having a predetermined frequency.

The electronic device 130 according to the present embodiment has been described in terms of its configuration. Similarly to the electronic component 10 according to the first embodiment, the electronic device 130 thus configured is mounted on the control board 100 serving as the mounting target member to configure a millimeter wave radar device. Specifically, as depicted in FIG. 8, the electronic device 130 is disposed such that the second surface 30b of the sealing member 30 faces the control board 100. The electronic device 130 is mounted on the control board 100 such that the joint member 110 such as solder is interposed between each of the first and second connection patterns 71 and 72 and the connection pattern of the control board 100. Each of the first connection pattern 71 and the second connection pattern 72 is thus electrically and mechanically connected to the control board 100 via the joint member 110.

The present embodiment provides the conductor patterns 73 functioning as antennas in this case. The control board 100 in a millimeter wave radar device thus needs no portion provided with the antenna 80. This achieves reduction in size of the control board 100, which will lead to reduction in size of the millimeter wave radar device.

The electronic device 130 is provided with the MMIC chip 90. In comparison to the case where the MMIC chip 90 is mounted on the control board 100, this configuration achieves decrease in length of wiring between each of the varactor diodes 20 and the MMIC chip 90. This leads to reduction in influence of noise.

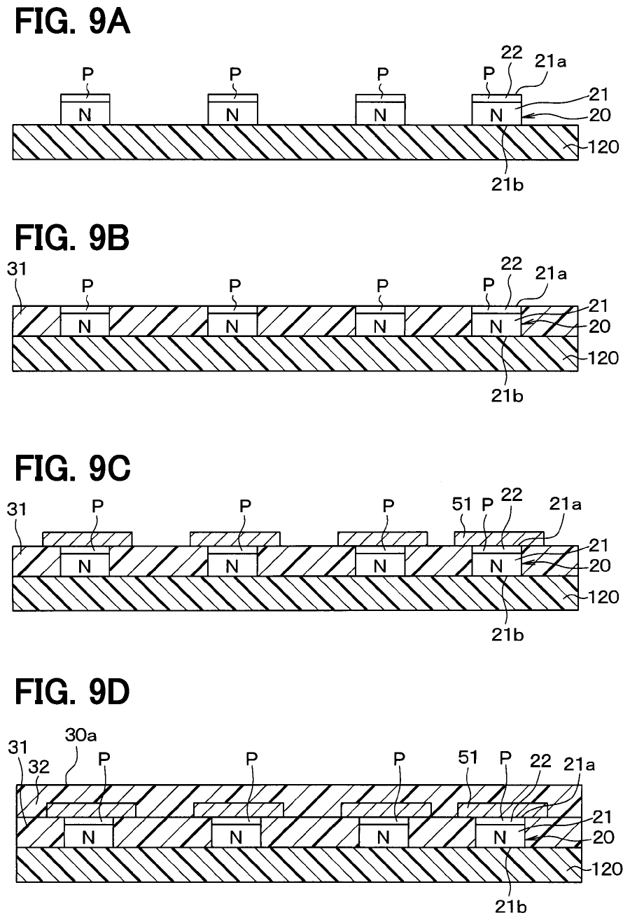

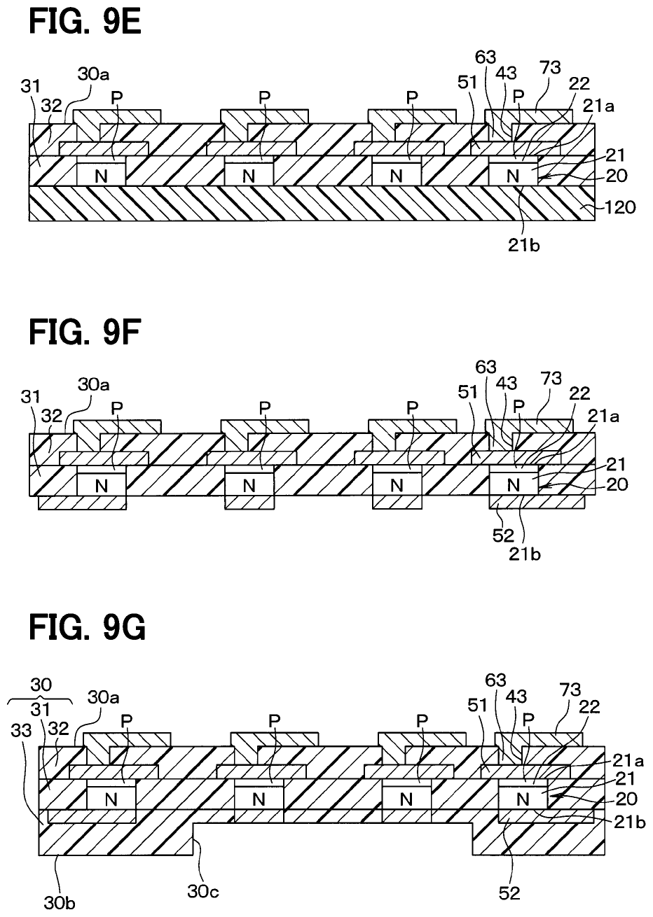

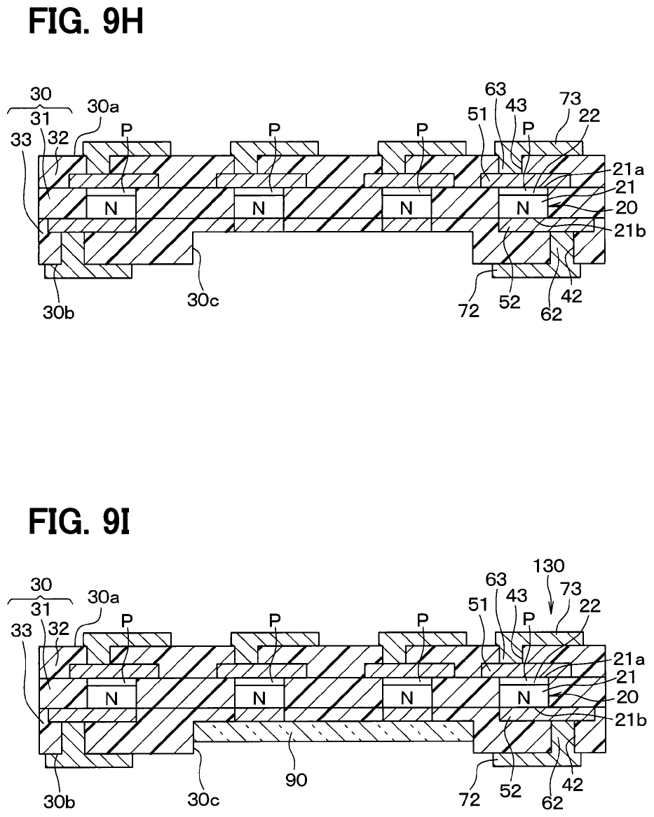

The electronic device 130 according to the present embodiment has been described in terms of its configuration. A method for producing the electronic device 130 will be described next with reference to FIG. 9A to FIG. 9I.

As depicted in FIG. 9A to FIG. 9D, the plurality of substrates 21 each provided with the varactor diode 20 is initially prepared and is subjected to steps similar to those depicted in FIG. 4A to FIG. 4D. Specifically, the plurality of substrates 21 is disposed on the preliminarily fixing member 120 as depicted in FIG. 9A, and the steps similar to those depicted in FIG. 4B to FIG. 4D are then executed as depicted in FIG. 9B to FIG. 9D to form the first sealing member 31, the first electrodes 51, and the second sealing member 32.

As depicted in FIG. 9E, laser light or the like is applied to the first surface 30a to form the third via holes 43 exposing the first electrodes 51. A metal film made of copper or the like is then formed by plating or the like to embed the third via holes 43, so as to achieve the third through vias 63. A metal film is then formed on the second sealing member 32 and is patterned to achieve the conductor patterns 73 respectively connected to the third through vias 63.

As depicted in FIG. 9F, a step similar to that depicted in FIG. 4E is subsequently executed to separate the preliminarily fixing member 120. The second electrodes 52 are then formed to be electrically respectively connected to the second surfaces 21b of the substrates 21.

As depicted in FIG. 9G, a step similar to that depicted in FIG. 4F is then executed to form the third sealing member 33, so as to provide the sealing member 30. The recess 30c provided in the sealing member 30 may be formed simultaneously with the third sealing member 33, or may be formed by applying laser light or the like after the third sealing member 33 is formed.

As depicted in FIG. 9H, laser light or the like is subsequently applied to the second surface 30b of the sealing member 30 to form the second via holes 42 exposing the second electrodes 52. A metal film is then formed by plating or the like to embed the second via holes 42, so as to achieve second through vias 62. A metal film is then formed on the third sealing member 33 and is patterned to achieve the second connection patterns 72 respectively connected to the second through vias 62.

In a step depicted in FIG. 9H, the first via holes 41 exposing the first electrodes 51 to the second surface 30b of the sealing member 30 are also formed in a section different from the section depicted in FIG. 9H. Furthermore, the first through vias 61 and the first connection patterns 71 are formed in this step.

As depicted in FIG. 9I, the MMIC chip 90 is then mounted in the recess 30c of the sealing member 30. The electronic device 130 depicted in FIG. 7 is achieved accordingly.

As described above, the electronic device 130 may include the conductor patterns 73 functioning as antennas. In this case, the control board 100 in a millimeter wave radar device needs no portion provided with the antenna 80. This achieves reduction in size of the control board 100, which will lead to reduction in size of the millimeter wave radar device.

The electronic device 130 is provided with the MMIC chip 90. In comparison to the case where the MMIC chip 90 is mounted on the control board 100, this configuration achieves decrease in length of wiring between each of the varactor diodes 20 and the MMIC chip 90. This leads to reduction in influence of noise.

### Third Embodiment

The third embodiment will be described below. The third embodiment is different from the second embodiment in that the plurality of varactor diodes 20 is provided on a single common substrate 21. The remaining configuration is similar to that according to the first embodiment and will thus not be described repeatedly.

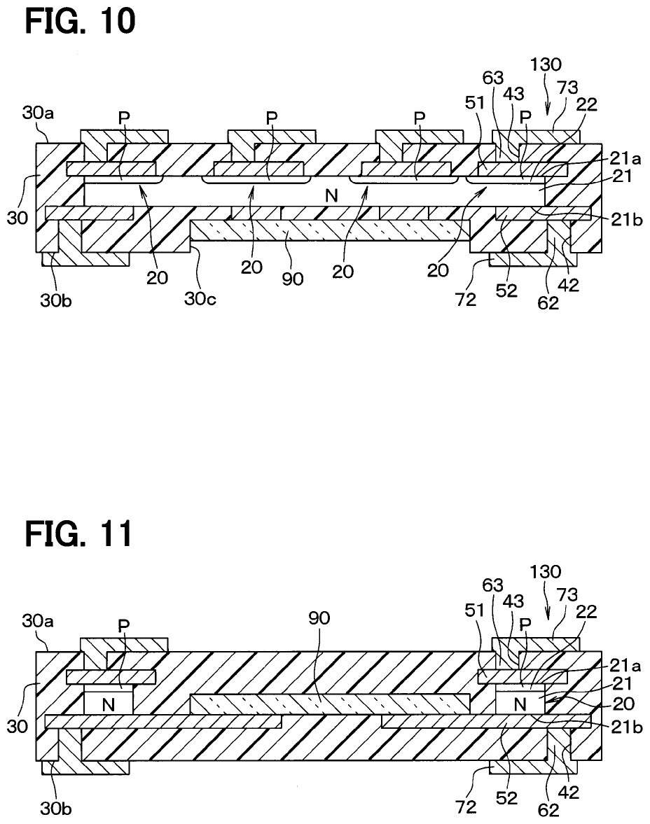

As depicted in FIG. 10, the plurality of varactor diodes 20 is provided on the common substrate 21 in the present embodiment. Though not particularly depicted, the varactor diodes 20 each have an element isolation structure such as a shallow trench isolation (abbreviated as STI) structure.

As described above, when the plurality of varactor diodes 20 is included, the varactor diodes 20 may be provided on the common substrate 21. The electronic device 130 thus configured achieves an effect similar to that of the second embodiment.

### Fourth Embodiment

The fourth embodiment will be described below. The fourth embodiment is different from the second embodiment in that the MMIC chip 90 is disposed inside the sealing member 30. The remaining configuration is similar to that according to the first embodiment and will thus not be described repeatedly.

As depicted in FIG. 11, the MMIC chip 90 is disposed inside the sealing member 30 in the present embodiment. Specifically, the MMIC chip 90 is positioned substantially flush with the substrates 21. The electronic device 130 thus configured may be produced, for example, through disposing the substrates 21 as well as the MMIC chip 90 on the preliminarily fixing member 120 in the step depicted in FIG. 9A.

This method does not need formation of the recess 30c to be provided with the MMIC chip 90, which leads to simplified production steps.

### Other Embodiments

The present disclosure is not limited to the embodiments described above, but can be modified appropriately within the scope recited in the disclosure.

For example, the substrate 21 according to each of the above embodiments may be configured by a silicone substrate.

The MMIC chip 90 according to the second embodiment may not be provided on the sealing member 30. The electronic device 130 thus configured and included in a millimeter wave radar device can cause the conductor patterns 73 to function as antennas to achieve reduction in size of the millimeter wave radar device.

The sealing member 30 according to the first embodiment may seal a plurality of substrates 21. Similarly, the sealing member 30 according to the second or fourth embodiment may seal a single substrate 21.

The first and second connection patterns 71 and 72 according to the first embodiment may be provided on the second surface 30b of the sealing member 30. Similarly, in any one of the second to fourth embodiments, the first and second connection patterns 71 and 72 may be provided on the first surface 30a of the sealing member 30 whereas the conductor patterns 73 may be provided on the second surface 30b of the sealing member 30.

While various embodiments, configurations, and aspects of electronic component and electronic device according to the present disclosure have been exemplified, the embodiments, configurations, and aspects of the present disclosure are not limited to those described above. For example, embodiments, configurations, and aspects obtained from an appropriate combination of technical elements disclosed in different embodiments, configurations, and aspects are also included within the scope of the embodiments, configurations, and aspects of the present disclosure.

What is claimed is:

1. An electronic component comprising:
a variable capacitance element;
a substrate that has the variable capacitance element;
a connection pattern that is electrically connected to the variable capacitance element and is also electrically connected to a mounting target member; and
a sealing member that has permittivity lower than that of the substrate and has insulation resistance higher than that of the substrate, the sealing member sealing the substrate,
wherein:
at least a part of the connection pattern is disposed on an outer surface of the sealing member.

2. An electronic device comprising:
a variable capacitance element;
a substrate that has the variable capacitance element;
a connection pattern that is electrically connected to the variable capacitance element and is also electrically connected to a mounting target member;
a sealing member that has permittivity lower than that of the substrate and has insulation resistance higher than that of the substrate, the sealing member sealing the substrate; and
a conductor pattern that is electrically connected to the variable capacitance element and is configured to function as an antenna,
wherein:
at least a part of the connection pattern is disposed on an outer surface of the sealing member; and
the conductor pattern is disposed on an outer surface of the sealing member.

3. The electronic device according to claim 2, further comprising:
an oscillator circuit that is electrically connected to the variable capacitance element and is configured to oscillate a radio wave having a predetermined frequency, the sealing member having the oscillator circuit.

4. The electronic device according to claim 2, wherein:
the sealing member seals the variable capacitance element.

5. The electronic device according to claim 4, further comprising:
a plurality of electronic components each including the variable capacitance element, the substrate, and the conductor pattern.

6. The electronic device according to claim 5, wherein:
the variable capacitance element is a varactor diode; and
the conductor patterns of the electronic components corresponds to an array antenna.

7. The electronic device according to claim 6, wherein:
the substrate is a gallium arsenide substrate; and
the sealing member is epoxy resin.
